(19) United States
(12) Patent Application Publication
(10) Pub. No.: US 2006/0065895 A1
(43) Pub. Date: Mar. 30, 2006

(54) Image display device

(76) Inventors: Toshiaki Kusunoki, Tokorozawa (JP); Masakazu Sagawa, Inagi (JP); Kazutaka Tsuji, Hachioji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/237,785

(22) Filed: Sep. 29, 2005

(30) Foreign Application Priority Data
Sep. 30, 2004 (JP) 2004-288489

(51) Int. Cl. H01L 29/76

(52) U.S. Cl. 257/66

(57) ABSTRACT

An interlayer insulator with a low taper angle is formed as a laminated film in which a silicon nitride film is formed on a silicon oxide film formed on the glass substrate side (field insulator side). Thus, an upper electrode of a cathode formed on the interlayer insulator is prevented from being broken, while a crossing portion between the upper electrode and a base electrode of the cathode is made low in capacitance. At the same time, sodium separated from glass of the substrate is blocked. Disconnection of the upper electrode is prevented due to the low taper angle of the interlayer insulator. Low capacitance is attained by increasing the film thickness of the interlayer insulator. The cathode is prevented from being contaminated with sodium separated from glass of the substrate.

### CLAIM OF PRIORITY

The present application claims priority from Japanese application JP 2004-288489 filed on Sep. 30, 2004, the content of which is hereby incorporated by reference into this application.

### FIELD OF THE INVENTION

The present invention relates to an image display device, and particularly relates to an image display device also referred to as an emissive flat panel display using thin-film electron emitter arrays.

### DESCRIPTION OF THE BACKGROUND ART

An image display device (Field Emission Display: FED) using field emission cathodes that are microscopic and can be integrated has been developed. The field emission cathodes are also referred to as thin-film cathodes. Cathodes of such an image display device are categorized into field emission cathodes and hot electron emission cathodes. The former includes Spindt type cathodes, surface-conduction electron emission cathodes, carbon-nanotube cathodes, and the like. The latter includes thin-film cathodes of an MIM (Metal-Insulator-Metal) type comprised of a metal-insulator-metal lamination, an MIS (Metal-Insulator-Semiconductor) type comprised of a metal-insulator-semiconductor lamination, a metal-insulator-semiconductor-metal type, and the like.

For example, the MIM type has been disclosed in Patent Document 1. An MOS type (disclosed in Non-Patent Document 1 or the like) has been reported as the metal-insulator-semiconductor type. An HEED type (disclosed in Non-Patent Document 2 or the like), an EL type (disclosed in Non-Patent Document 3 or the like), a porous silicon type (disclosed in Non-Patent Document 4 or the like), etc. have been reported as the metal-insulator-semiconductor-metal type.

For example, an MIM type cathode is disclosed in Patent Document 2. The structure and operation of the MIM type cathode will be described below. That is, the MIM type cathode has a structure in which an insulator is inserted between an upper electrode and a base electrode. When a voltage is applied between the upper electrode and the base electrode, electrons near the Fermi level in the base electrode penetrate a barrier due to a tunneling phenomenon, so as to be injected into a conductive band of the insulator serving as an electron accelerator. Hot electrons formed thus flow into a conductive band of the upper electrode. Of the hot electrons, ones reaching the surface of the upper electrode with energy not smaller than a work function φ of the upper electrode are released to the vacuum.

Patent Document 1:
Japanese Patent Laid-Open No. 65710/1995

Patent Document 2:
Japanese Patent Laid-Open No. 153979/1998
US2004/012476/A1

Non-Patent Document 1:
j. Vac. Sci. Techonol. B11(2) p. 429-432 (1993)

Non-Patent Document 2:
high-efficiency-electro-emission device, Jpn, j, Appl, Phys, vol. 36, pp. 939

Non-Patent Document 3:
Electroluminescence, Oyo Buturi, vol. 63, No. 6, pp. 592

Non-Patent Document 4:
Oyo Buturi, vol. 66, No. 5, pp. 437

Such cathodes are arranged in a plurality of rows (for example, horizontally) and a plurality of columns (for example, vertically) so as to form a matrix. A large number of phosphors arrayed correspondingly to the cathodes respectively are disposed in the vacuum. Thus, an image display device can be configured. In order to perform image display in the image display device configured thus, a driving method called “one line at a time driving scheme” is adopted typically. This is a system in which, when 60 still images (60 frames) per second are displayed, each frame is displayed by scan line (horizontally). Accordingly, all the cathodes corresponding to the number of data lines on one and the same scan line are activated concurrently. A current flowing into the scan lines which are active can be obtained by multiplying, by the total number of scan lines, a current consumed by cathodes included in sub-pixels (sub-pixels constituting a color pixel for full color display). This scan line current leads to a voltage drop along the scan lines due to wiring resistance, so as to prevent uniform operation of the cathodes. Particularly in order to attain a large-size display device, the voltage drop caused by the wiring resistance of the scan lines becomes a large problem.

In order to solve the problem, it is necessary to reduce the wiring resistance of the scan lines. In the case of a thin-film cathode, it can be considered to reduce the resistance in a base electrode or an upper bus electrode (scan line) for supplying power to an upper electrode. However, when the thickness of the base electrode is increased to reduce the resistance, the irregularities of the wiring may be intense, the quality of an electron accelerator may deteriorate, or the upper bus electrode or the like may be broken easily. Thus, there occurs a problem in reliability. It is therefore preferable to use a method for reducing the resistance of the upper bus electrode so as to use the upper bus electrode as a scan line.

In order to reduce the resistance of the upper bus electrode, it is effective to form the upper bus electrode as a laminated wire in which aluminum Al is sandwiched in chrome Cr from above and below. An upper electrode of the cathode is formed from the upper bus electrode to the cathode so as to be supplied with power from the upper bus electrode.

That is, the power supply path from the upper bus electrode to the upper electrode is formed by the upper electrode formed to extend onto the upper bus electrode along the side edge of an interlayer insulator for insulating the upper electrode from the base electrode outside the electron accelerator put between the upper electrode serving as a cathode and the base electrode.

In the MIM type cathode, in order to transmit hot electrons, the upper electrode is formed to be extremely thin to be not thicker than 10 nm. To this end, it has been a problem to attain tapering with a low angle in the side edge of the interlayer insulator. In addition, in the image display device using such MIM type cathodes, a frame glass is put between a cathode substrate and a phosphor substrate while vacuum sealing is attained using frit glass. To this end, soda lime based glass whose thermal expansion coefficient is approximate to that of the frit glass is used for the cathode substrate and the phosphor substrate. The soda lime based glass separates out sodium Na in heat treatment in a process of vacuum sealing. The separated sodium Na contaminates electron emitters (cathodes). Thus, how to suppress the contamination of the cathodes with Na has been a problem.

Further, in the device in which the upper bus electrodes serving as scan lines and the base electrodes of the cathodes serving as data lines are disposed in a matrix, it is requested to make the capacitance between adjacent lines as small as possible so as to reduce the current load and the power consumption of the driving circuit. In order to reduce the capacitance between the lines, how to thicken each interlayer insulator has been a problem.

### SUMMARY OF THE INVENTION

An object of the present invention is to provide an image display device in which the taper angle of an interlayer insulator is made low enough to prevent an upper electrode from being broken, so that the interlayer insulator is made thick enough to reduce the capacitance, while a cathode is prevented from being contaminated with sodium separated from glass of a substrate.

In order to attain the foregoing object, according to the present invention, a laminated film of a silicon oxide film and a silicon nitride film, a laminated film of a silicon oxynitride film and a silicon nitride film, or a silicon oxynitride film having a composition gradient in which the concentration of nitrogen is low on the glass substrate side (field insulator side) and high on the surface side abutting against the upper electrode, is used as the interlayer insulator.

That is, the present invention provides an image display device including:

a cathode substrate including a large number of thin-film cathodes disposed in a matrix, each of the thin-film cathodes including a base electrode, an upper electrode and an electron accelerator retained between the base electrode and the upper electrode, each of the thin-film cathodes emitting electrons from the side of the upper electrode in a region where the electron accelerator is laminated, in response to a voltage applied between the base electrode and the upper electrode; and

a phosphor substrate including phosphor layers of a plurality of colors disposed correspondingly to the cathodes respectively; wherein:

the base electrode and the upper electrode are insulated from each other outside the aforementioned region of the electron accelerator by a laminated insulator of a field insulator and an interlayer insulator, the field insulator being contiguous to the electron accelerator, the interlayer insulator being formed on the field insulator;

the upper electrode is formed to extend from a side edge of the laminated insulator of the field insulator and the interlayer insulator so as to cover the upper bus electrode located on the interlayer insulator and for feeding power to the upper electrode; and

the interlayer insulator is made of a laminated film of a silicon oxide film and a silicon nitride film, the silicon oxide film being located on the field insulator side, the silicon nitride film being located on the upper bus electrode side.

The present invention also provides an image display device including:

a cathode substrate including a large number of thin-film cathodes disposed in a matrix, each of the thin-film cathodes including a base electrode, an upper electrode and an electron accelerator retained between the base electrode and the upper electrode, each of the thin-film cathodes emitting electrons from the side of the upper electrode in a region where the electron accelerator is laminated, in response to a voltage applied between the base electrode and the upper electrode; and

a phosphor substrate including phosphor layers of a plurality of colors disposed correspondingly to the cathodes respectively; wherein:

the base electrode and the upper electrode are insulated from each other outside the aforementioned region of the electron accelerator by a laminated insulator of a field insulator and an interlayer insulator, the field insulator being contiguous to the electron accelerator, the interlayer insulator being formed on the field insulator;

the upper electrode is formed to extend from a side edge of the laminated insulator of the field insulator and the interlayer insulator so as to cover the upper bus electrode located on the interlayer insulator and for feeding power to the upper electrode; and

the interlayer insulator is made of a laminated film of a silicon oxynitride film and a silicon nitride film, the silicon oxynitride film being located on the field insulator side, the silicon nitride film being located on the upper bus electrode side.

The present invention also provides an image display device including:

a cathode substrate including a large number of thin-film cathodes disposed in a matrix, each of the thin-film cathodes including a base electrode, an upper electrode and an electron accelerator retained between the base electrode and the upper electrode, each of the thin-film cathodes emitting electrons from the side of the upper electrode in a region where the electron accelerator is laminated, in response to a voltage applied between the base electrode and the upper electrode; and

a phosphor substrate including phosphor layers of a plurality of colors disposed correspondingly to the cathodes respectively; wherein:

the base electrode and the upper electrode are insulated from each other outside the aforementioned region of the electron accelerator by a laminated insulator of a field insulator and an interlayer insulator, the field insulator being contiguous to the electron accelerator, the interlayer insulator being formed on the field insulator;

the upper electrode is formed to extend from a side edge of the laminated insulator of the field insulator and the interlayer insulator so as to cover the upper bus electrode located on the interlayer insulator and for feeding power to the upper electrode; and

the interlayer insulator is made of a laminated film of a silicon oxynitride film and a silicon nitride film formed on the silicon oxynitride film, and the silicon oxynitride film has a concentration gradient in which nitrogen concentration is low on the field insulator side and high on the silicon nitride film side.

The present invention also provides an image display device including:

a cathode substrate including a large number of thin-film cathodes disposed in a matrix, each of the thin-film cathodes including a base electrode, an upper electrode and an electron accelerator retained between the base electrode and the upper electrode, each of the thin-film cathodes emitting electrons from the side of the upper electrode in a region where the electron accelerator is laminated, in response to a voltage applied between the base electrode and the upper electrode; and

a phosphor substrate including phosphor layers of a plurality of colors disposed correspondingly to the cathodes respectively; wherein:

the base electrode and the upper electrode are insulated from each other outside the aforementioned region of the electron accelerator by a laminated insulator of a field insulator and an interlayer insulator, the field insulator being contiguous to the electron accelerator, the interlayer insulator being formed on the field insulator;

the upper electrode is formed to extend from a side edge of the laminated insulator of the field insulator and the interlayer insulator so as to cover the upper bus electrode located on the interlayer insulator and for feeding power to the upper electrode; and

the interlayer insulator is made of a silicon oxynitride film having a concentration gradient in which silicon oxide concentration is high on the field insulator side and silicon nitride concentration is high on the upper bus electrode side.

The upper bus electrode according to the present invention is formed to have a three-layer structure in which aluminum Al or an aluminum alloy is used as a metal film intermediate layer, and sandwiched between a metal film lower layer and a metal film upper layer both made of chromium Cr or a chromium alloy from above and below. Further, the metal film lower layer projects over the metal film intermediate layer on one side surface of the upper bus electrode so as to be connected to the upper electrode. On the other side surface of the upper bus electrode opposite to the aforementioned one side surface, the metal film lower layer forms an undercut with respect to the metal film intermediate layer, and the upper electrode is separated from adjacent pixels by the undercut.

According to the present invention, the taper angle of the edge of the interlayer insulator can be made small enough to prevent disconnection in the upper electrode formed between the cathode and the upper bus electrode. In addition, due to the small taper angle of the interlayer insulator, it is easy to thicken the interlayer insulator. Accordingly, it is possible to reduce the capacitance of the crossing portion where a scan signal electrode crosses the data line, that is, a scan signal electrode crosses the base electrode of the cathode and is connected to the upper electrode. Thus, high-speed driving can be attained so that an image can be displayed with high definition. Further, the cathode can be prevented from being contaminated with sodium separated from the substrate glass. Thus, it is possible to provide an image display device in which deterioration of performance of each cathode can be suppressed, the life of the image display device can be prolonged, and electron emission can be performed with high efficiency.

### BRIEF DESCRIPTION OF THE DRAWINGS

FIG. 1 is a schematic plan view for explaining Embodiment 1 of the present invention, showing an image display device using MIM thin-film cathodes by way of example;

FIG. 2 is a diagram showing the principle of operation of a thin-film cathode;

FIG. 3 is a diagram showing a process for manufacturing a thin-film cathode according to the present invention;

FIG. 4 is a diagram following FIG. 3, showing the process for manufacturing the thin-film cathode according to the present invention;

FIG. 5 is a diagram following FIG. 4, showing the process for manufacturing the thin-film cathode according to the present invent ion;

FIG. 6 is a diagram following FIG. 5, showing the process for manufacturing the thin-film cathode according to the present invention;

FIG. 7 is a diagram following FIG. 6, showing the process for manufacturing the thin-film cathode according to the present invention;

FIG. 8 is a diagram following FIG. 7, showing the process for manufacturing the thin-film cathode according to the present invention;

FIG. 9 is a diagram following FIG. 8, showing the process for manufacturing the thin-film cathode according to the present invention;

FIG. 10 is a diagram following FIG. 9, showing the process for manufacturing the thin-film cathode according to the present invention;

FIG. 11 is a diagram following FIG. 10, showing the process for manufacturing the thin-film cathode according to the present invention;

FIG. 12 is a main portion sectional view for explaining the configuration of Embodiment 1 of an interlayer insulator according to the present invention;

FIG. 13 is a main portion sectional view for explaining the configuration of Embodiment 2 of an interlayer insulator according to the present invention; and

FIG. 14 is a main portion sectional view for explaining the configuration of Embodiment 3 of an interlayer insulator according to the present invention.

### BEST MODE FOR CARRYING OUT THE INVENTION

The best mode for carrying out the present invention will be described below in detail with reference to the drawings and in connection with embodiments.

First, an example of an image display device according to the present invention will be described as an image display device using hot electron emission MIM type cathodes. However, the present invention is not limited to such MIM type cathodes. Not to say, the present invention is applicable to an image display device using various electron emission devices described in the chapter of the background art, in the same manner.

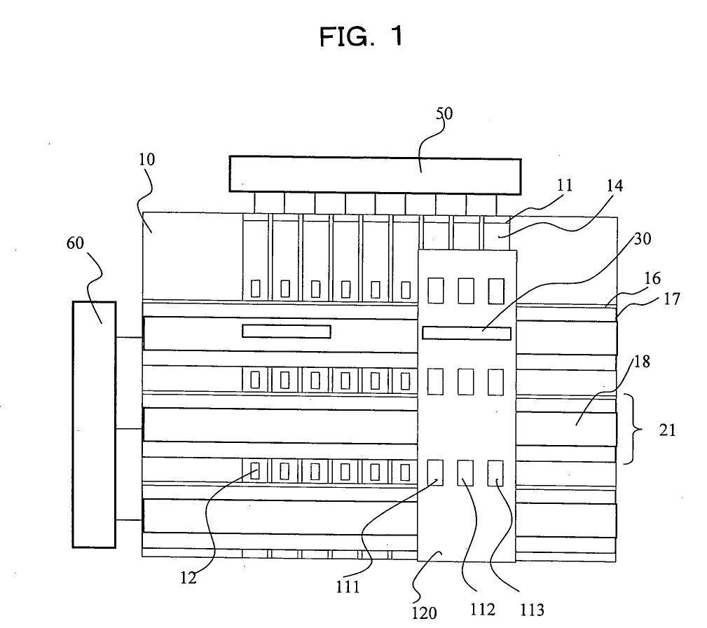

FIG. 1 is a view for explaining Embodiment 1 of the present invention and a schematic plan view of an image display device using MIM thin-film cathodes by way of example. In FIG. 1, one glass substrate (cathode substrate) 10 chiefly having cathodes is shown in plan view, while the other glass substrate (phosphor substrate, display-side substrate, or color filter substrate) where phosphors are formed partially is not shown but only a black matrix 120 and phosphors 111, 112 and 113 included in the inner surface of the other glass substrate are shown partially.

In the cathode substrate 10, there are formed base electrodes 11, a metal film lower layer 16, a metal film intermediate layer 17, a metal film upper layer 18, protective insulators (field insulators) 14, other functional films which will be described later, etc. The base electrodes 11 constitute signal lines (data lines or data electrodes) connected to a data line driving circuit 50. The metal film lower layer 16, the metal film intermediate layer 17 and the metal film upper layer 18 form scan lines (scan electrodes) 21 connected to a scan line driving circuit 60 and disposed perpendicularly to the data lines. Each cathode (electron emission portion or electron source) is formed out of an upper electrode (not shown) connected to the upper bus electrode and laminated to the base electrode 11 through the insulator. Electrons are released from the portion of an insulator (tunneling insulator) 12 formed out of a thin layer portion of the insulator.

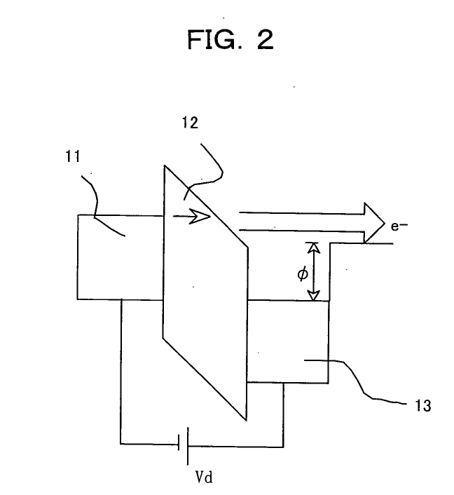

FIG. 2 is a diagram for explaining the principle of the MIM type cathode. In the cathode, when a driving voltage Vd is applied between the upper electrode 13 and the base electrode 11 so as to set the electric field in the tunneling insulator 12 at about 1-10 MV/cm, electrons near the Fermi level in the base electrode 11 penetrate a barrier due to a tunneling phenomenon, so as to be injected into a conductive band of the insulator 12 serving as an electron accelerator. Hot electrons formed thus flow into a conductive band of the upper electrode 13. Of the hot electrons, ones reaching the surface of the upper electrode 13 with energy not smaller than a work function φ of the upper electrode 13 are released to the vacuum.

Referring to FIG. 1 again, the inner surface of the display-side substrate is comprised of the black matrix 120, the red phosphors 111, the green phosphors 112 and the blue phosphors 113. The black matrix 120 serves as a light shielding layer for increasing the contrast of a displayed image. For example, Y₂O₂S:Eu(p22-R), ZnS:Cu,Al(p22-G) and ZnS:Ag,Cl(p22-B) can be used as the red, green, and blue phosphors respectively. The cathode substrate 10 and the phosphor substrate are retained at a predetermined interval from each other by spacers 30 made of glass plates or ceramics plates. A frame glass (sealing frame, not shown) is inserted in the outer circumference of a display region so as to vacuum-seal the inside of the display region.

The spacers 30 are disposed on the upper bus electrodes of the scan electrodes 21 of the cathode substrate 10 so as to be hidden under the black matrix 120 of the phosphor substrate. The base electrodes 11 are connected to the data line driving circuit 50, and the scan electrodes 21 serving as the upper bus electrodes are connected to the scan line driving circuit 60.

In the cathode structure according to Embodiment 1, the upper bus electrode is formed to have a laminated structure in which a low-resistance wire of Al or an Al alloy is sandwiched in Cr, a Cr alloy or the like having heat resistance and oxidation resistance. Accordingly, the upper electrode 13 can be processed to be self-aligned, and the upper bus electrode can be produced so that the upper bus electrode will not deteriorate even after the sealing process. Thus, a voltage drop due to the wiring resistance of the display device can be suppressed. In addition, due to the thick spacer electrodes 21, the thin-film cathodes can be prevented from being mechanically damaged by the spacers bearing the atmospheric pressure.

In each of the MIM type cathodes shown in FIG. 1, the base electrode 11 serving as a data electrode, the tunneling insulator 12 and the upper electrode 13 are laminated on the cathode substrate 10 so as to form an electron emission portion. A portion other than the tunneling insulator 12 is electrically separated from the scan electrode by the field insulator 14 and the interlayer insulator 15. The upper electrode 13 is connected to one scan electrode 21 on one side of its wiring, and separated on the other side by the undercut of the lower Cr or Cr alloy layer 16. Thus, the scan electrode can be electrically separated from the other scan electrodes (that is, pixels adjacent to each other in the scan direction can be separated from each other).

The scan electrode 21 serving as the upper bus electrode is made of a three-layer lamination in which Al or an Al alloy high in oxidation resistance is sandwiched in Cr or a Cr alloy from above and below. Due to the heat resistance and the oxidation resistance of Cr or the Cr alloy, damage on wiring can be avoided in the process or the like where the panel of the image display device is sealed at a high temperature. In addition, the request for reduction in resistance of wiring can be also satisfied when the wiring is thickened by use of the Al or Al alloy layer low in resistivity. For example, an Al—Nd alloy including with 2 at % of Nd can be used as the Al alloy, and a Cr—Mo alloy including 50 wt % of Mo can be used as the Cr alloy. Here, description will be made on the assumption that Al may include an Al alloy and Cr may include a Cr alloy.

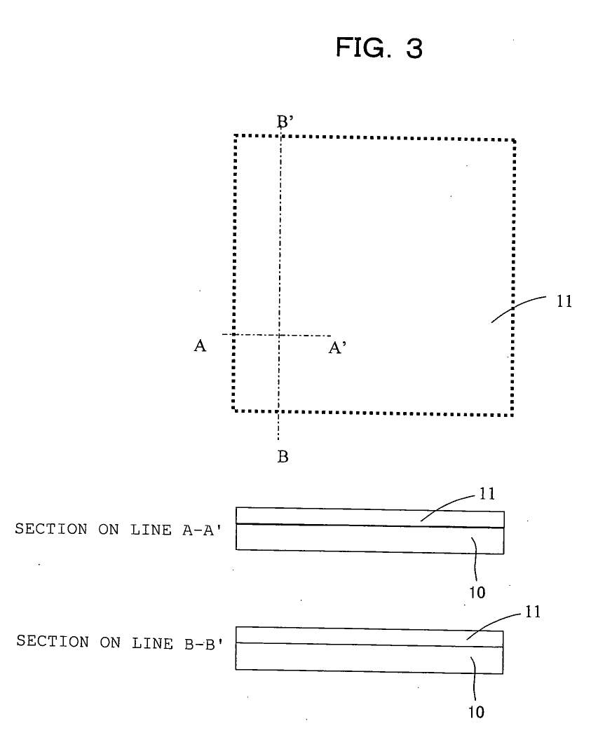

Next, an embodiment of the method for manufacturing the image display device according to the present invention will be described with reference to FIGS. 3-11 showing a process for manufacturing a scan electrode according to Embodiment 1. First, as shown in FIG. 3, a metal film serving as the base electrode 11 is formed on an insulating substrate 10 of glass or the like. Al is used as the material of the base electrode 11. The reason why Al is used is that a high quality insulating film can be formed by anodic oxidation. Here, an Al—Nd alloy doped with 2 at % of Nd is used. For example, a sputtering method is used for forming the film. The thickness of the film is made 300 nm.

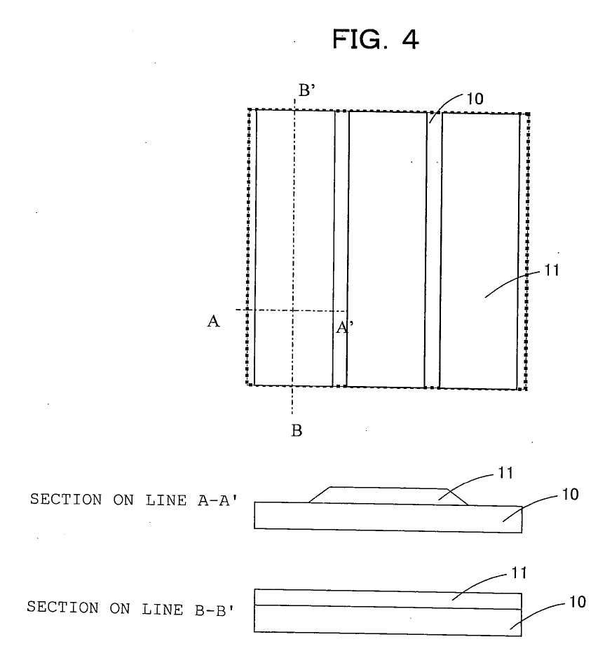

After the film formation, the base electrode 11 having a stripe shape is formed by a patterning process and an etching process (FIG. 4). The base electrode 11 varies in electrode width in accordance with the size or resolution of the image display device, but the electrode width is made as large as the pitch of sub-pixels thereof, that is, approximately 100-200 microns. For example, wet etching with a mixed aqueous solution of phosphoric acid, acetic acid and nitric acid is used for the etching. Since this electrode has a wide and simple stripe structure, resist patterning can be performed by inexpensive proximity exposure, printing or the like.

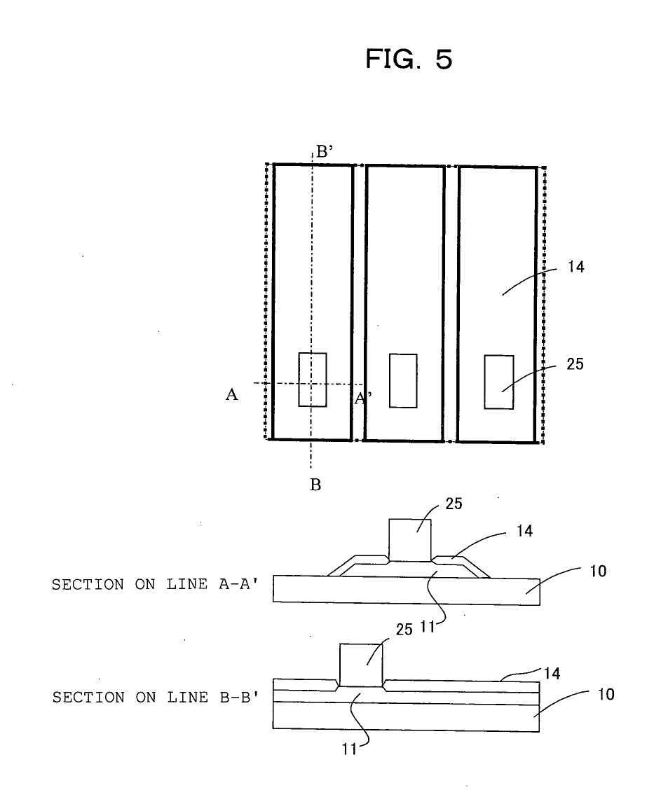

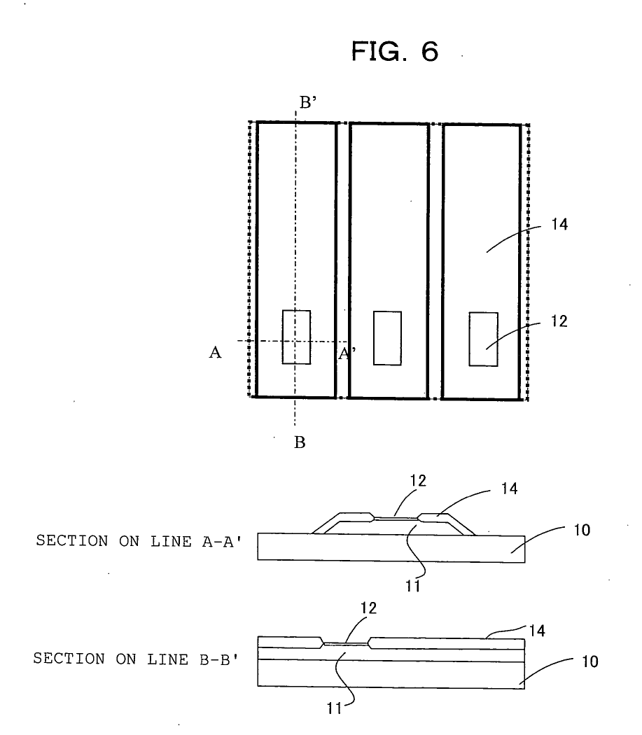

Next, a protective insulator (also referred to as “field insulator”) 14 for limiting an electron emission portion and preventing electric field concentration on the edge of the base electrode 11, and an insulator (also referred to as “tunneling insulator”) 12 are formed. First, a portion which will be an electron emission portion on the base electrode 11 as shown in FIG. 5 is masked with a resist film 25, and the other portion is selectively anodized thickly so as to be formed as the protective insulator 14. When chemical conversion voltage is set at 100 V, the protective insulator 14 is formed to be about 136 nm thick. After that, the resist film 25 is removed, and the remaining surface of the base electrode 11 is anodized. When the chemical conversion voltage in this event is, for example, set at 6 V, the insulator (tunneling insulator) 12 is formed to be about 10 nm thick on the base electrode 11 (see FIG. 6).

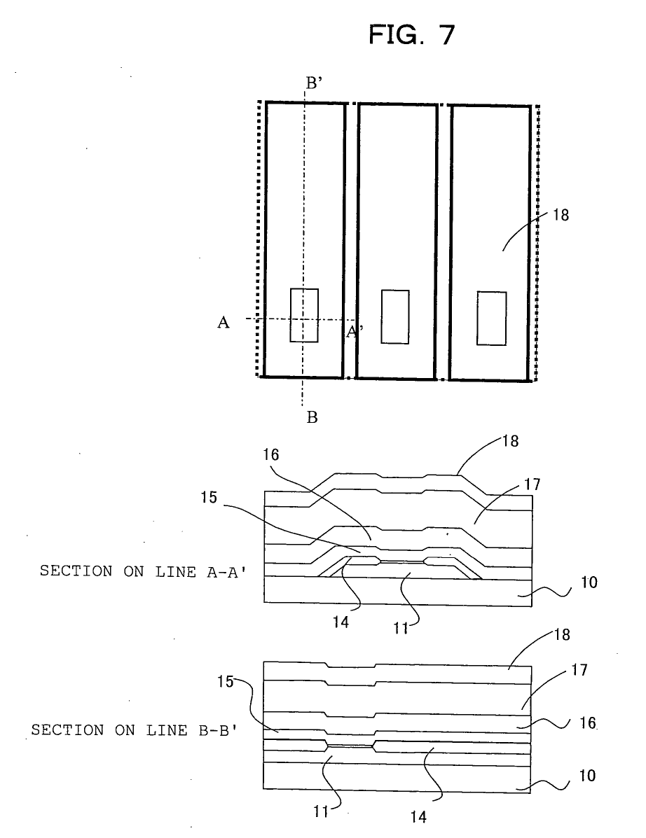

Next, an interlayer insulator 15, and a metal film serving as an upper bus electrode serving as a power feeder to the upper electrode 13 and a spacer electrode for disposing a spacer 30 so as to electrically connect the spacer 30 with the upper bus electrode are formed, for example, by a sputtering method or the like (FIG. 7). If there is a pin hole in the protective insulator 14 formed by anodic oxidation, the pin hole will be filled with the interlayer insulator 15 so that the interlayer insulator 15 will serve to keep insulation between the base electrode 11 and the upper bus electrode. The metal film has a three-layer film in which Al as a metal film intermediate layer 17 is put between a metal film lower layer 16 and a metal film upper layer 18 both made of Cr.

Here, Al is used for the metal film intermediate layer 17, and Cr is used for the metal film lower layer 16 and the metal film upper layer 18. The film thickness of Al is made as thick as possible in order to reduce the wiring resistance. Here, the metal film lower layer 16 is made 100 nm thick, the metal film intermediate layer 17 is made 4 μm thick, and the metal film upper layer 18 is made 100 nm thick.

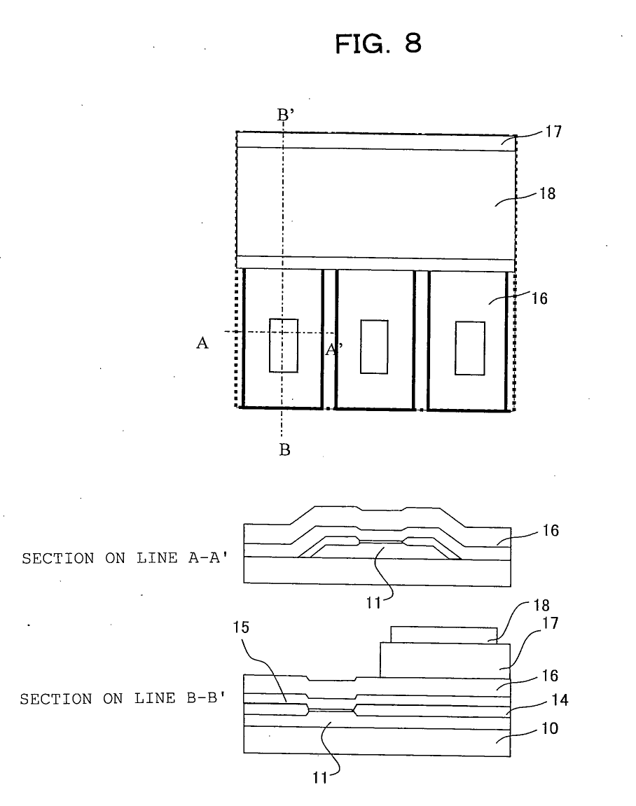

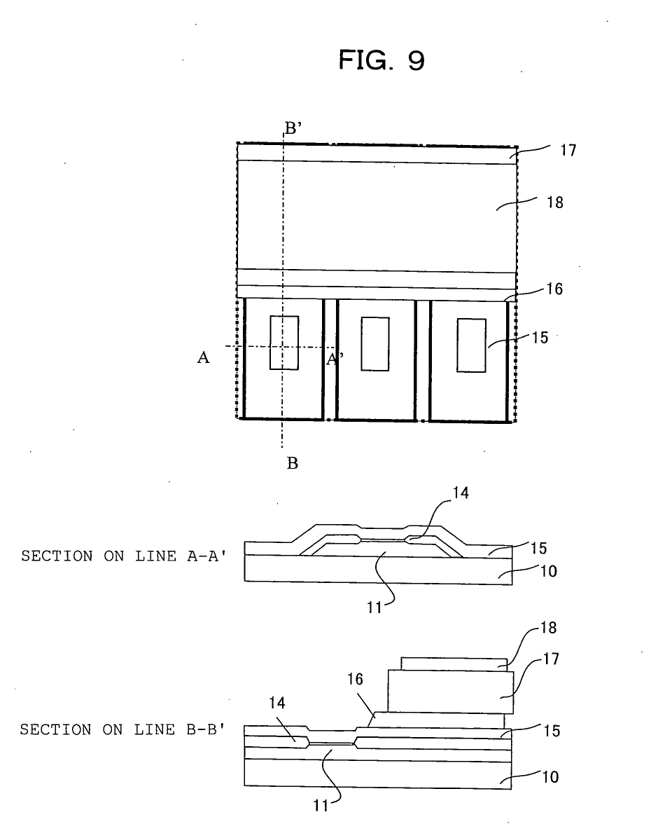

Successively, the metal film upper layer 18 is formed into a stripe shape perpendicular to the base electrode 11 by patterning and etching. For example, wet etching with a cerium ammonium nitrate solution is used for the etching (FIG. 8). Successively, the metal film lower layer 16 is processed into a stripe shape perpendicular to the base electrode 11 by patterning and etching (FIG. 9). Wet etching with a mixed aqueous solution of phosphoric acid and acetic acid is used for the etching. In this event, one side (cathode formation side) of the metal film lower layer 16 is made to project over the metal film upper layer 18 so as to serve as a contact portion for securing connection with the upper electrode in a subsequent process. On the other side (opposite side to the cathode formation side) of the metal film lower layer 16, an undercut is formed using the metal film upper layer 18 as a mask so as to form an appentice for separating the upper electrode 13 from the other upper electrodes 13 in a subsequent process. Thus, it is possible to form an upper bus electrode which self-aligns the upper electrode 13 so as to separate the upper electrode 13 from the other upper electrodes 13 and feed power to the upper electrode 13.

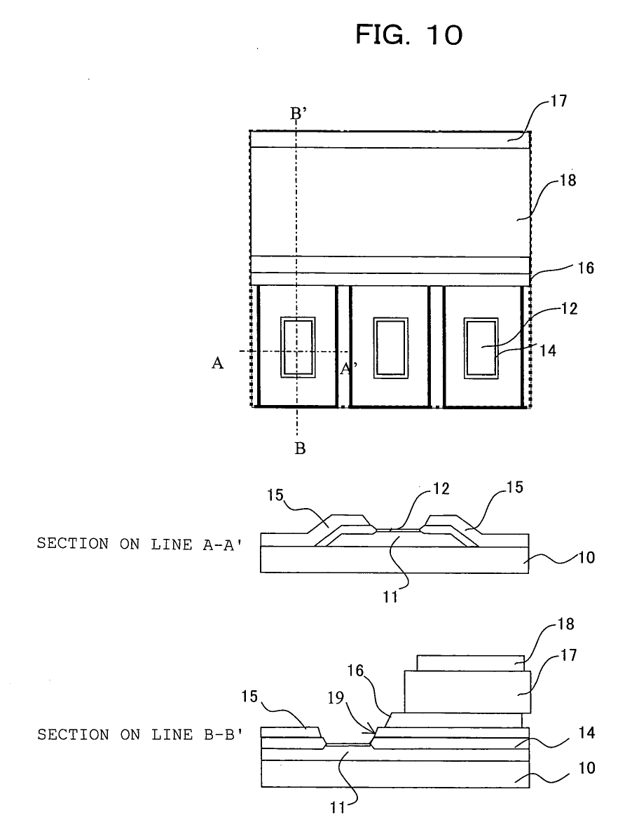

Successively, the interlayer insulator 15 is etched to open an electron emission portion. The electron emission portion is formed in a part of a perpendicular portion of a space surrounded by one base electrode 11 of a sub-pixel and two upper bus electrodes perpendicular to the base electrode 11. For example, dry etching with an etching agent having CF₄ or SF₆ as its main component can be used for the etching (FIG. 10).

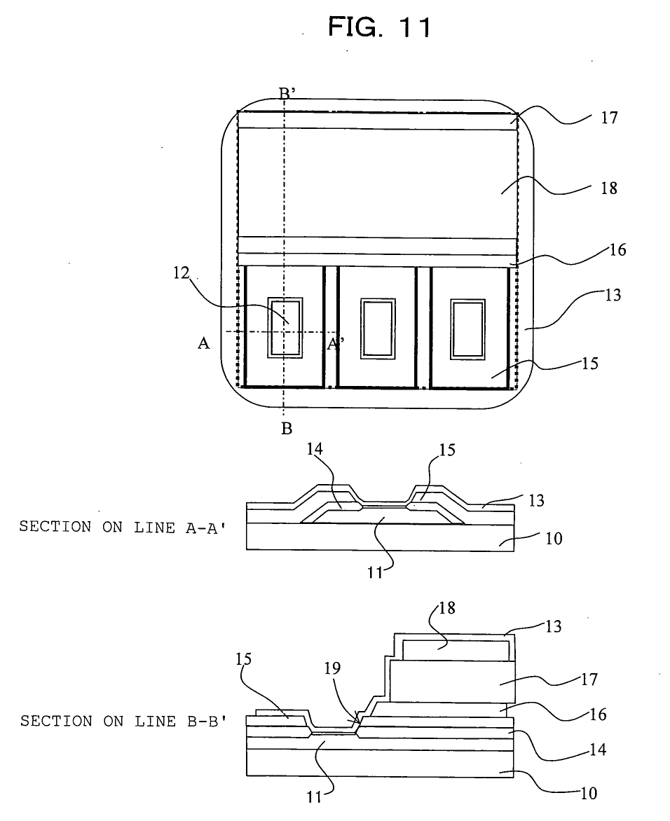

Finally, the upper electrode film 13 is formed. For example, sputtering film formation is used as the method for forming the film. A laminated film of Ir, Pt and Au is used as the upper electrode 13, and the film thickness is made 6 nm by way of example. In this event, the upper electrode 13 has a structure in which the upper electrode 13 is cut by the appentice structure in one of the two upper bus electrodes sandwiching the electron emission portion, while the upper electrode 13 is connected to the other upper bus electrode through the contact portion of the metal film lower layer 16 without disconnection so as to be supplied with power (FIG. 11). Examples of interlayer insulators according to the present invention will be described below.

### Embodiment 1

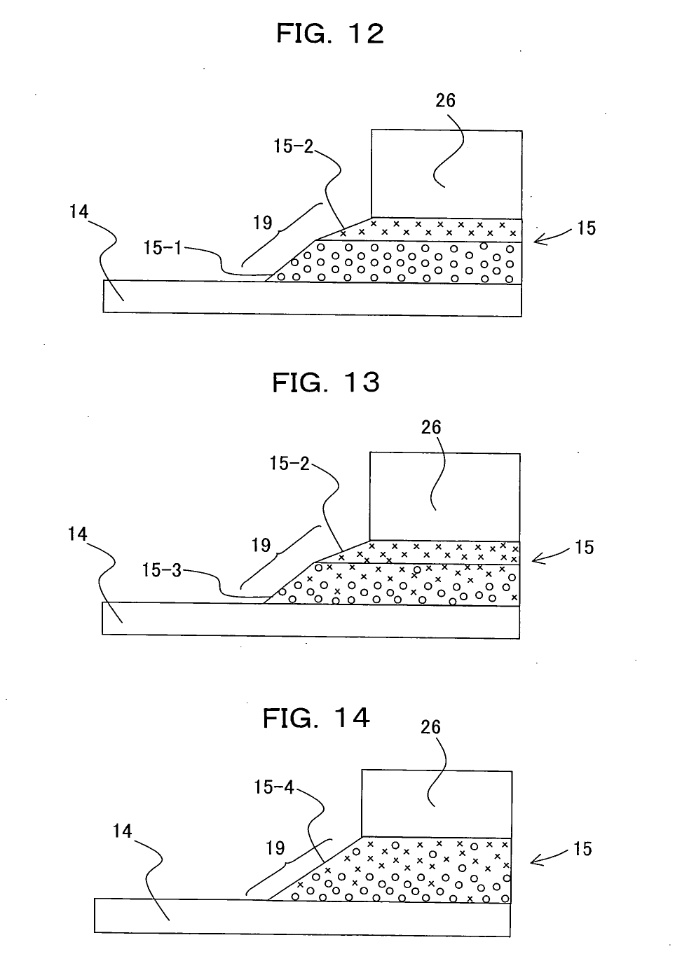

FIG. 12 is a main portion sectional view for explaining the configuration of Embodiment 1 of an interlayer insulator according to the present invention. In FIG. 12, the field insulator 14 is formed on the base electrode 11 shown in FIG. 11, and the base electrode 11 is formed on the cathode substrate 10 made of a glass plate. However, the base electrode 11 and the cathode substrate 10 are not shown in FIG. 12.

In Embodiment 1, the interlayer insulator 15 is constituted by a laminated film of a lower layer 15-1 and an upper layer 15-2. The lower layer 15-1 is made of a silicon oxide film SiO₂, and formed on the field insulator 14, and a silicon nitride film SiN is formed thereon as the upper layer 15-2. A photo-resist 26 is applied onto the laminated film. The photo-resist 26 is applied to expose a region so as to be formed as a taper.

The silicon oxide film SiO₂ and the silicon nitride film SiN have different dry etching rates. The dry etching rate of the silicon oxide film SiO₂ 15-1 having a large content of oxygen is low, and the dry etching rate of the silicon nitride film SiN 15-2 having a large content of nitrogen is higher than that of the silicon oxygen film SiO₂. The silicon nitride film SiN 15-2 is etched at a higher rate than the silicon oxide film SiO₂ 15-1 on the glass substrate side (field insulator 14 side) regardless of the amount of additional oxygen in dry etching gas. Thus, a taper 19 as shown in FIG. 12 is formed.

After the etching, the photo-resist 26 is removed, and the upper electrode 13 is formed. In this event, the upper electrode 13 is formed to extend from the cathode along the taper 19 of the interlayer insulator 15 and cover the upper bus electrode. Since there is no step in the interlayer insulator 15, there is no fear that the upper electrode 13 is disconnected in this portion.

The interlayer insulator is formed so that a silicon compound having a high content of nitrogen high in Na blocking capacity is laminated on a silicon compound having a high content of oxygen low in permittivity. Accordingly, the crossing portion between the data line (base electrode 11) and the upper electrode 13 (scan line, upper bus electrode) can be made low in capacitance, while contamination of the cathode with sodium Na diffused from the glass substrate can be blocked. It is therefore possible to obtain an image display device high in reliability, high in definition and long in life.

### Embodiment 2

FIG. 13 is a main portion sectional view for explaining the configuration of Embodiment 2 of an interlayer insulator according to the present invention. Also in FIG. 13, in the same manner as in FIG. 12, the field insulator 14 is formed on the base electrode 11 shown in FIG. 11, and the base electrode 11 is formed on the cathode substrate 10 made of a glass plate. However, the base electrode 11 and the cathode substrate 10 are not shown in FIG. 13.

In Embodiment 2, the interlayer insulator 15 is constituted by a laminated film of a lower layer 15-3 and an upper layer 15-2. The lower layer 15-3 is made of a silicon oxynitride film SiO₂ (x) N (y), and formed on the field insulator 14. Here, (x) designates the content of silicon oxide SiO₂, and (y) designates the content of silicon nitride SiN. A silicon nitride film SiN is formed as the upper layer 15-2 on the silicon oxynitride film SiO₂(x)N(y).

The silicon oxynitride film SiO₂(x)N(y) 15-3 is a film with a composition gradient in which the value (x) is remarkably larger than the value (y) on the field insulator 14 side, that is, the silicon oxynitride film SiO₂(x)N(y) 15-3 is rich in silicon oxide SiO₂ on the field insulator 14 side, while the value (y) is remarkably larger on the upper-layer silicon nitride film SiN side, that is, the silicon oxynitride film SiO₂(x)N(y) 15-3 is rich in silicon nitride SiN on the silicon nitride film SiN side. A photo-resist 26 is applied onto the laminated film of the silicon oxynitride film SiO₂(x)N(y) and the silicon nitride film SiN so as to expose a region to be formed as a taper.

For the same reason as in Embodiment 1, the dry etching rate of the silicon oxynitride film SiO₂(x)N(y) 15-3 on the field insulator 14 side with a rich oxygen content is low while the dry etching rate of the silicon oxynitride film SiO₂(x) N (y) 15-3 on the silicon nitride film SiN 15-2 side is high. A taper is formed in the silicon oxynitride film SiO₂(x)N(y) 15-3 on the glass substrate side (field insulator 14 side) regardless of the amount of additional oxygen in dry etching gas. Likewise a taper is formed in the upper-layer silicon nitride film SiN 15-2 having a higher etching rate. Thus, a taper 19 as shown in FIG. 13 is formed. Instead of the film with a composition gradient as described above, a homogeneous composition film in which the value (x) is approximately equal to the value (y) may be used as the silicon oxynitride film SiO₂(x)N(y) 15-3. Even in this case, a required taper angle as a whole can be formed in the edge of the interlayer insulator though the shape of the formed taper is slightly large.

After the etching, the photo-resist 26 is removed, and the upper electrode 13 is formed. In this event, the upper electrode 13 is formed to extend from the cathode along the taper 19 of the interlayer insulator 15 and cover the upper bus electrode. Since there is no step in the interlayer insulator 15, there is no fear that the upper electrode 13 is disconnected in this portion.

The interlayer insulator is formed so that a silicon compound having a high content of nitrogen high in Na blocking capacity is laminated on a silicon compound having a high content of oxygen low in permittivity. Accordingly, the crossing portion between the data line (base electrode 11) and the upper electrode 13 (scan line, upper bus electrode) can be made low in capacitance, while contamination of the cathode with sodium Na diffused from the glass substrate can be blocked. It is therefore possible to obtain an image display device high in reliability, high in definition and long in life.

### Embodiment 3

FIG. 14 is a main portion sectional view for explaining the configuration of Embodiment 3 of an interlayer insulator according to the present invention. Also in FIG. 14, the field insulator 14 is formed on the base electrode 11 shown in FIG. 11, and the base electrode 11 is formed on the cathode substrate 10 made of a glass plate. However, the base electrode 11 and the cathode substrate 10 are not shown in FIG. 14.

In Embodiment 3, as the interlayer insulator 15, only a silicon oxynitride film SiO₂ (x)N(y) 15-4 having a composition gradient similar to that of the lower layer in Embodiment 2 is formed on the field insulator 14. Here, (x) designates the content of silicon oxide SiO₂, and (y) designates the content of silicon nitride SiN.

In the silicon oxynitride film SiO₂(x)N(y) 15-4, the value (x) is remarkably larger than the value (y) on the field insulator 14 side, that is, the silicon oxynitride film SiO₂(x)N(y) 15-4 is rich in silicon oxide SiO₂ on the field insulator 14 side, while the value (y) is remarkably larger on the upper bus electrode formation side (top surface side), that is, the silicon oxynitride film SiO₂(x)N(y) 15-4 is rich in silicon nitride SiN on the top surface side. A photo-resist 26 is applied onto the silicon oxynitride film SiO₂(x)N(y) so as to expose a region to be formed as a taper. In this event, the photo-resist 26 may be applied to a portion which is ahead of the region to be formed as a taper. In this case, the etching rate varies continuously in accordance with the concentrations of silicon oxide SiO₂ and silicon nitride SiN so that a taper angle 19 as shown in FIG. 14 can be obtained.

That is, for the same reason as in Embodiment 2, the dry etching rate of the silicon oxynitride film SiO₂(x)N(y) 15-4 on the field insulator 14 side with a rich oxygen content is low while the dry etching rate of the silicon oxynitride film SiO₂(x)N(y) 15-4 on the top surface side is high. A taper is formed in the silicon oxynitride film SiO₂(x)N(y) 15-4 on the glass substrate side (field insulator 14 side) regardless of the amount of additional oxygen in dry etching gas. Thus, a taper 19 as shown in FIG. 14 is formed.

After the etching, the photo-resist 26 is removed, and the upper electrode 13 is formed. In this event, the upper electrode 13 is formed to extend from the cathode along the taper 19 of the interlayer insulator 15 and cover the upper bus electrode. Since there is no step in the interlayer insulator 15, there is no fear that the upper electrode 13 is disconnected in this portion.

The interlayer insulator is formed so that a silicon compound having a high content of nitrogen high in Na blocking capacity is laminated on a silicon compound having a high content of oxygen low in permittivity. Accordingly, the crossing portion between the data line (base electrode 11) and the upper electrode 13 (scan line, upper bus electrode) can be made low in capacitance, while contamination of the cathode with sodium Na diffused from the glass substrate can be blocked. It is therefore possible to obtain an image display device high in reliability, high in definition and long in life.

The silicon oxynitride film SiO₂(x)N(y) in FIGS. 13, 14 can be obtained by varying the amount of additional oxygen and the amount of additional nitrogen discontinuously or continuously in a reactive sputtering method using a silicon target. Alternatively, the silicon oxynitride film SiO₂(x)N(y) can be obtained by varying the amount of additional oxide material (SiH₄—N₂O, O₂, etc.) and the amount of additional nitride material (SiH₄—NH₃, H₂, etc.) discontinuously or continuously in raw material gas in plasma CVD.

What is claimed is:

1. An image display device comprising:
a cathode substrate including a large number of thin-film cathodes disposed in a matrix, each of said thin-film cathodes including a base electrode, an upper electrode and an electron accelerator retained between said base electrode and said upper electrode, each of said thin-film cathodes emitting electrons from the side of said upper electrode in a region where said electron accelerator is laminated, in response to a voltage applied between said base electrode and said upper electrode; and
a phosphor substrate including phosphor layers of a plurality of colors disposed correspondingly to said cathodes respectively; wherein:
each of said thin-film cathodes has an interlayer insulator outside said region of said electron accelerator, said interlayer insulator insulating said base electrode from an upper bus electrode serving as a power feeder to said upper electrode;
said upper electrode is formed to extend from a side edge of said interlayer insulator so as to cover said upper bus electrode located on said interlayer insulator and for feeding power to said upper electrode; and
said interlayer insulator is made of a laminated film of a silicon oxide film and a silicon nitride film.

2. An image display device according to claim 1, wherein said silicon nitride film of said laminated film is located on the side of said upper bus electrode.

3. An image display device comprising:
a cathode substrate including a large number of thin-film cathodes disposed in a matrix, each of said thin-film cathodes including a base electrode, an upper electrode and an electron accelerator retained between said base electrode and said upper electrode, each of said thin-film cathodes emitting electrons from the side of said upper electrode in a region where said electron accelerator is laminated, in response to a voltage applied between said base electrode and said upper electrode; and
a phosphor substrate including phosphor layers of a plurality of colors disposed correspondingly to said cathodes respectively; wherein:
each of said thin-film cathodes has an interlayer insulator outside said region of said electron accelerator, said interlayer insulator insulating said base electrode from an upper bus electrode serving as a power feeder to said upper electrode;
said upper electrode is formed to extend from a side edge of said interlayer insulator so as to cover said upper bus electrode located on said interlayer insulator and for feeding power to said upper electrode; and
said interlayer insulator is made of a laminated film of a silicon oxynitride film and a silicon nitride film.

4. An image display device according to claim 3, wherein said silicon nitride film of said laminated film is located on the side of said upper bus electrode.

5. An image display device comprising:
a cathode substrate including a large number of thin-film cathodes disposed in a matrix, each of said thin-film cathodes including a base electrode, an upper electrode and an electron accelerator retained between said base electrode and said upper electrode, each of said thin-film cathodes emitting electrons from the side of said upper electrode in a region where said electron accelerator is laminated, in response to a voltage applied between said base electrode and said upper electrode; and
a phosphor substrate including phosphor layers of a plurality of colors disposed correspondingly to said cathodes respectively; wherein:
each of said thin-film cathodes has an interlayer insulator outside said region of said electron accelerator, said interlayer insulator insulating said base electrode from an upper bus electrode serving as a power feeder to said upper electrode;
said upper electrode is formed to extend from a side edge of said interlayer insulator so as to cover said upper bus electrode located on said interlayer insulator and for feeding power to said upper electrode; and
said interlayer insulator is a laminated film made of a silicon oxynitride film and a silicon nitride film formed on said silicon oxynitride film, and said silicon oxynitride film has a concentration gradient in which nitrogen concentration is high on the side of said silicon nitride film.

6. An image display device comprising:
a cathode substrate including a large number of thin-film cathodes disposed in a matrix, each of said thin-film cathodes including a base electrode, an upper electrode and an electron accelerator retained between said base electrode and said upper electrode, each of said thin-film cathodes emitting electrons from the side of said upper electrode in a region where said electron accelerator is laminated, in response to a voltage applied between said base electrode and said upper electrode; and
a phosphor substrate including phosphor layers of a plurality of colors disposed correspondingly to said cathodes respectively; wherein:
each of said thin-film cathodes has an interlayer insulator outside said region of said electron accelerator, said interlayer insulator insulating said base electrode from an upper bus electrode serving as a power feeder to said upper electrode;
said upper electrode is formed to extend from a side edge of said interlayer insulator so as to cover said upper bus electrode located on said interlayer insulator and for feeding power to said upper electrode; and
said interlayer insulator is made of a silicon oxynitride film having a composition gradient in which silicon nitride concentration is high on the side of said upper bus electrode.

7. An image display device according to claim 1, wherein said upper bus electrode is formed to have a three-layer structure in which aluminum or an aluminum alloy is used as a metal film intermediate layer, and sandwiched between a metal film lower layer and a metal film upper layer both made of chromium or a chromium alloy from above and below.

8. An image display device according to claim 1, wherein:
said upper bus electrode is formed to have a three-layer structure in which aluminum or an aluminum alloy is used as a metal film intermediate layer, and sandwiched between a metal film lower layer and a metal film upper layer both made of chromium or a chromium alloy from above and below;
said metal film lower layer projects over said metal film intermediate layer on one side surface of said upper bus electrode so as to be connected to said upper electrode;
said metal film lower layer forms an undercut with respect to said metal film intermediate layer on the other side surface of said upper bus electrode opposite to said one side surface; and
said upper electrode is separated from adjacent pixels by said undercut.

9. An image display device according to claim 1, wherein said upper bus electrode is used as a scan line during matrix driving.
